(19) United States
(12) Patent Application Publication
(10) Pub. No.: US 2025/0215264 A1
(43) Pub. Date: Jul. 3, 2025

(54) SLURRY COMPOSITION FOR CHEMICAL MECHANICAL POLISHING, METHOD OF PREPARING SAME, AND CHEMICAL MECHANICAL POLISHING METHOD OF WAFER

(71) Applicant: Samsung Electronics Co., Ltd., Suwon-si (KR)

(72) Inventors: Seokhwan LEE, Suwon-si (KR); Inkwon KIM, Suwon-si (KR)

(73) Assignee: Samsung Electronics Co., Ltd., Suwon-si (KR)

(21) Appl. No.: 18/828,576

(22) Filed: Sep. 9, 2024

(30) Foreign Application Priority Data
Dec. 28, 2023 (KR) 10-2023-0195141

(51) Int. Cl. C09G 1/02; H01L 21/02

(52) U.S. Cl. CPC C09G 1/02; H01L 21/0201

(57) ABSTRACT

Provided are a slurry composition for chemical mechanical polishing including an abrasive including dendrimer particles surface-treated with metal oxide, a method of preparing same, and a chemical mechanical polishing method of a wafer.

### CROSS-REFERENCE TO RELATED APPLICATION

This application claims priority to and the benefit of Korean Patent Application No. 10-2023-0195141 filed in the Korean Intellectual Property Office on Dec. 28, 2023, the entire contents of which are incorporated herein by reference.

### BACKGROUND

### 1. Field

The present disclosure relates to a slurry composition for chemical mechanical polishing, a method of preparing same, and a chemical mechanical polishing method of a wafer.

### 2. Description of the Related Art

A chemical mechanical polishing (CMP) apparatus is used in a polishing process of planarizing a surface of a wafer. In general, a semiconductor device is manufactured by selectively or repeatedly performing processes such as photolithography, etching, diffusion, chemical vapor deposition, ion implantation, or metal deposition on a wafer. In the process, the wafer may undergo a chemical mechanical polishing (CMP) process such as planarization process to etch back and to facilitate formation of a circuit pattern on the surface.

The CMP process may include supplying a slurry so that the slurry is uniformly distributed on a surface of a polishing pad rotating at high speed, and placing the surface of the wafer for which planarization is required near the surface of the polishing pad, thereby processing a target surface of the wafer through a chemical action by the slurry and a physical action by high-speed rotation.

Meanwhile, when polishing memory and logic semiconductor devices of 5 nm or less in the CMP process, scratches occur, which reduces yield and causes problems in subsequent processes. This is a problem after the CMP process that occurs as the line width narrows in semiconductor microprocessing, and the development of slurry technology with a high polishing rate and micro-scratches is necessary to improve yield.

### SUMMARY

An embodiment provides a slurry composition for chemical mechanical polishing that has excellent polishing performance on a wafer and reduces the occurrence of scratches or defects on the surface.

Another embodiment provides a method for preparing the slurry composition for chemical mechanical polishing.

Another embodiment provides a method for chemical mechanical polishing of a wafer using the slurry composition for chemical mechanical polishing.

An embodiment provides a slurry composition for chemical mechanical polishing including an abrasive including dendrimer particles surface-treated with metal oxide.

Another embodiment provides a method for preparing a slurry composition for chemical mechanical polishing, which includes preparing an abrasive including dendrimer particles surface-treated with metal oxide.

Another embodiment provides a chemical mechanical polishing method of a wafer applying the slurry composition for chemical mechanical polishing to a wafer.

The slurry composition for chemical mechanical polishing according to at least one embodiment not only has excellent polishing performance on the wafer, but can also suppress the occurrence of scratches or defects on the wafer surface.

### BRIEF DESCRIPTION OF THE DRAWINGS

FIG. 1 is a schematic view showing a chemical mechanical polishing apparatus.

FIG. 2 is a schematic view showing a wafer being polished using a slurry composition for chemical mechanical polishing according to at least one embodiment.

FIG. 3 is a schematic view showing an abrasive according to at least one embodiment.

FIG. 4 is a schematic view showing a wafer polishing process using a slurry composition for chemical mechanical polishing according to at least one embodiment.

### DETAILED DESCRIPTION

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

To clearly describe the present invention, parts that are not relevant to the description may be omitted, and like numerals refer to like or similar constituent elements throughout the specification.

The size and thickness of each constituent element as shown in the drawings are randomly indicated for better understanding and ease of description, and this disclosure is not necessarily limited to as shown. Additionally, whenever a range of values is enumerated, the range includes all values within the range as if recorded explicitly clearly, and may further include the boundaries of the range. Accordingly, a value provided as “within a range of ‘X’ to ‘Y’” includes all values between X and Y, including X and Y. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

Further, throughout the specification, the phrase “a plan view” means when an object portion is viewed from above, and the phrase “a cross-sectional view” means when a cross-section taken by vertically cutting an object portion is viewed from the side.

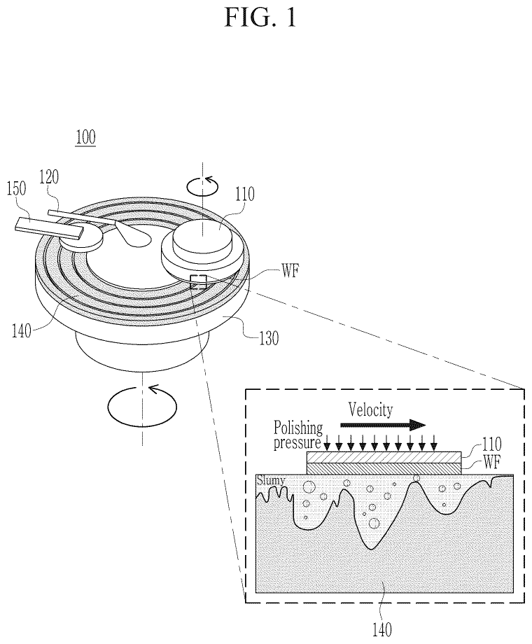

FIG. 1 is a schematic view showing a chemical mechanical polishing apparatus.

Referring to FIG. 1, a chemical mechanical polishing apparatus 100 is an apparatus for polishing a wafer WF, and includes a head unit 110, a slurry supplier 120, a polishing platen 130, a polishing pad 140, and a conditioner 150. The chemical mechanical polishing apparatus 100 is configured to perform a CMP process including a mechanical polishing while the wafer WF mounted on a bottom of the head unit 110 is in contact with the polishing pad 140, and a chemical polishing through a chemical reaction by a slurry supplied from the slurry supplier 120.

Referring to FIG. 1, the head unit 110 may be a rotatable member on which a wafer WF can be mounted. Specifically, the head unit 110 is configured to rotate in a certain direction. The head unit 110 may be configured to be pressed in a direction of the polishing pad 140 so that the wafer WF is polished. For example, at least some embodiments, the head unit 110 may be configured to be moved vertically along a first axis, and to be rotated around the first axis. In at least one embodiment, the head unit 110 may be connected to an assembly including, e.g., a piston, gear box, motor and/or the like configured to position and/or rotate the head unit 110. The head unit 110 may include a chuck (e.g., a vacuum chuck, electrostatic chuck, etc.) configured to hold the wafter WF.

The slurry supplier 120 may be a member configured to supply the slurry composition to the polishing pad 140. For example, the slurry supplier 120 may be disposed above the polishing pad 140, and to supply the slurry composition to the polishing pad 140. The slurry composition is transferred to the wafer through micropores formed in the polishing pad 140, so that mechanical polishing (by rotation of the head unit 110) and chemical polishing (by the slurry composition) can be performed simultaneously.

Specifically, the slurry supplier 120 may include an injection port and a pipe for delivering the slurry composition. The injection port may be disposed adjacent to the polishing pad 140. Accordingly, the slurry composition can be supplied onto the polishing pad 140 through the pipe and injection port. In at least one embodiment, the injection port of the slurry supplier 120 may be configured to be positioned over a center portion of the polishing platen 130 and/or the polishing pad 140. In this example, centripetal force, resulting from the rotation of the polishing pad 140, may be used to distribute the slurry. Additionally, in at least one embodiment, the slurry supplier 120 may be configured to move over the polishing platen 130 and/or the polishing pad 140 during the supplying of the slurry.

A detailed description of the slurry composition will be provided later.

The polishing platen 130 is disposed below the polishing pad 140, and may be a member that applies rotational energy so that the polishing pad 140 can rotate in a certain direction. For example, in at least one embodiment, the polishing platen 130 may be configured to rotate around a second axis, parallel to the first axis, and/or may be connected to an assembly including, e.g., a gear box, motor and/or the like configured to rotate the polishing platen 130. In some embodiments, the height of the polishing platen 130 may be adjustable or static. For example, in some embodiments, the height of the polishing platen 130 may be in adjusted to meet the head unit 110 and/or the height of the polishing platen 130 may be static such that the head unit 110 is adjusted to meet the polishing platen.

The polishing pad 140 is configured to be disposed on the polishing platen 130, and may be rotatable while being supported by the polishing platen 130. For example, the polishing pad 140 may be rotated by the rotation of the polishing platen 130. The polishing pad 140 uniformly planarizes the surface of the wafer WF, and may be a member that performs mechanical polishing.

The polishing pad 140 may include polyurethane, but is not limited thereto.

The conditioner 150 may be disposed adjacent to the aforementioned polishing pad 140. The conditioner 150 may perform a conditioning process on the polishing pad 140. Accordingly, the conditioner 150 can stably maintain a state of the polishing surface of the polishing pad 140 so that the wafer WF is effectively polished during the chemical mechanical polishing process.

Specifically, the conditioner 150 may maintain the surface roughness of the polishing pad 140 in an optimal (and/or near optimal) state by polishing the surface of the polishing pad 140. More specifically, the conditioner 150 finely cuts the surface of the polishing pad 140 to prevent numerous foam micropores, which serve to contain the slurry mixed with the abrasive and chemicals on the surface of the polishing pad 140, from being clogged, thereby allowing the slurry filled in the foam micropores of the polishing pad 140 to be smoothly supplied to the wafer WF.

The wafer WF may be, as a non-limiting example, a semiconductor wafer made of silicon as a base material and having a circular shape. As a non-limiting example, the wafer WF may consist of a member made of a material other than silicon, such as gallium arsenide, sapphire, gallium nitride, ceramics, resin, or silicon carbide, and may not have a device formed thereon.

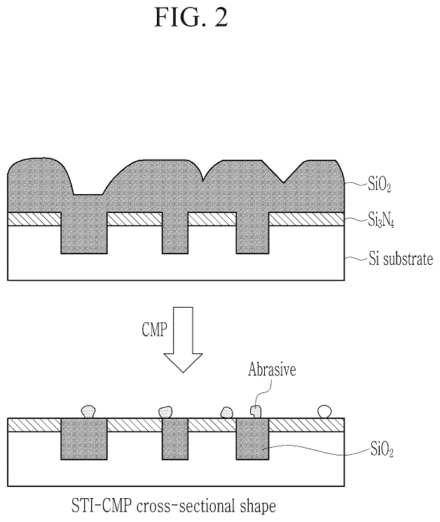

According to one implementation, the wafer WF may have, for example, a structure as shown in FIG. 2.

FIG. 2 is a schematic view showing a wafer being polished using a slurry composition for chemical mechanical polishing according to at least one embodiment.

Referring to FIG. 2, the slurry composition for chemical mechanical polishing according to at least one embodiment may be used, for example, in a shallow trench isolation (STI) CMP process. That is, the wafer has a silicon nitride and an oxide film, such as silicon dioxide, sequentially disposed on a silicon substrate, and the oxide film may have a trench structure that extends to the inside of the silicon substrate. The wafer can be polished using the slurry composition for chemical mechanical polishing according to at least one embodiment, and specifically, the oxide film disposed thereon can be polished. However, the examples are not limited thereto, and, for example, the wafer may include sequentially deposited structures including other compositions.

Hereinafter, the slurry composition supplied to the slurry supplier 120 will be described.

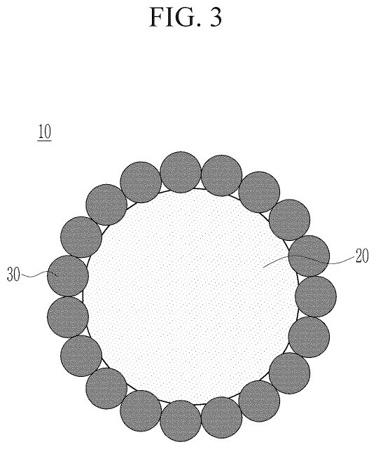

A slurry composition for chemical mechanical polishing according to at least one embodiment includes an abrasive. The abrasive is explained with reference to FIG. 3.

### Abrasive

FIG. 3 is a schematic view showing an abrasive according to at least one embodiment.

Referring to FIG. 3, the abrasive includes dendrimer particles (surface-treated with metal oxide) 10. The dendrimer particles (surface-treated with metal oxide) 10 specifically include dendrimer particles 20 and a metal oxide 30 surrounding at least a portion of the surface of the dendrimer particles 20.

Scratches and defects generated under pressure from the polishing pad during the polishing stage of the CMP process may cause unetching and pattern defects in subsequent processes. When a slurry composition including the aforementioned abrasive is used for chemical mechanical polishing, the central dendrimer particles 20 have elastic and flexible properties and thus serve as a cushion for the hard metal oxide 30, thereby reducing scratches and defects during polishing. In addition, while maintaining the polishing effect due to the metal oxide 30 treated on the surface, the surface area that can react when pressed by the elasticity of the dendrimer particles 20 during polishing also increases, allowing a high polishing rate.

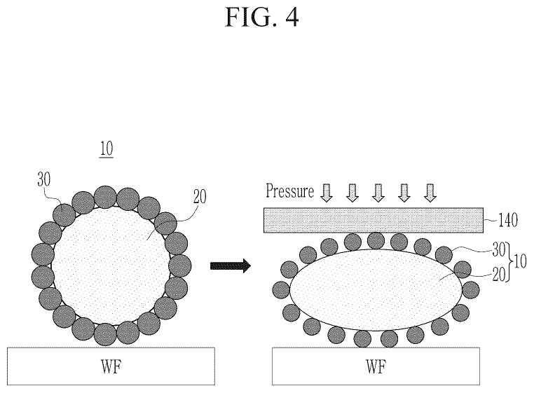

FIG. 4 is a schematic view showing a wafer polishing process using a slurry composition for chemical mechanical polishing according to at least one embodiment.

Referring to FIG. 4, if the dendrimer particles (surface-treated with metal oxide) 10 including the dendrimer particles 20 and the metal oxide 30 surrounding at least a portion of the surface of the dendrimer particles 20 is used as an abrasive for polishing a wafer WF, the surface area of the metal oxide 30 contacting the surface of the wafer may increase (due to elasticity of the dendrimer particles 10) thereby securing a high polishing rate, and in addition, the dendrimer particles 10, which are soft, act as a cushion to suppress scratch generation.

The dendrimer particles 20 may be nanoparticles monodispersed with high stability and accordingly, may be easily surface-treated and have soft properties.

The dendrimer particles 20 are a polymer with a regular branch structure, and specifically, a dendritic polymer in which the branch-shaped unit structure repeatedly extends from its core. The dendrimer particles 20 have an empty center and a reactive group selected to react with various chemical units at the terminal end.

The dendrimer particles 20 may have various reactive groups at the terminal ends, for example, an amino group, a hydroxy group, a carboxyl group, an acetyl group, a mannose group, a galactose group, or a combination thereof. Surface treatment of dendrimer particles becomes easier due to the reactive groups present at the terminal end.

Additionally, the dendrimer particles 20 may have a regularly repeating unit structure. A stage that a dendrimer grows is called a generation, wherein one generation increases whenever a regularly repeating unit structure is added. In at least some examples, a generation number of dendrimer particles 20 may be an integer from 1 to 10, for example 1, 2, 3, 4, 5, 6, 7, 8, 9 or 10. If the dendrimer particle has the generation number within the range, an abrasive with an appropriate size may exhibit excellent polishing performance and also suppress scratches and defects.

For example, the dendrimer particles 20 may have a unit structure such as —N—R¹—CO—NR²—R³— (wherein R¹ and R³ are each independently a single bond or a C1 to C10 alkylene group and R² is hydrogen or a C1 to C10 alkyl group), —N—R⁴— (wherein R⁴ is a single bond or a C1 to C10 alkylene group), —C—R⁵—OCO— (wherein R⁵ is a single bond or a C1 to C10 alkylene group), and the like.

The dendrimer particles 20 may include, for example, poly(amidoamine) (PAMAM), polypropyleneimine (PPI), or a combination thereof.

The poly(amidoamine) (PAMAM) is a dendritic polymer and can be formed by sequentially reacting ammonia or an amine compound with a carboxylic acid derivative compound and a diamine compound. As an example, when the dendrimer particles 20 are poly(amidoamine) (PAMAM), the abrasive, that is the dendrimer particles (surface-treated with metal oxide) 10, may be represented by Chemical Formula 1.

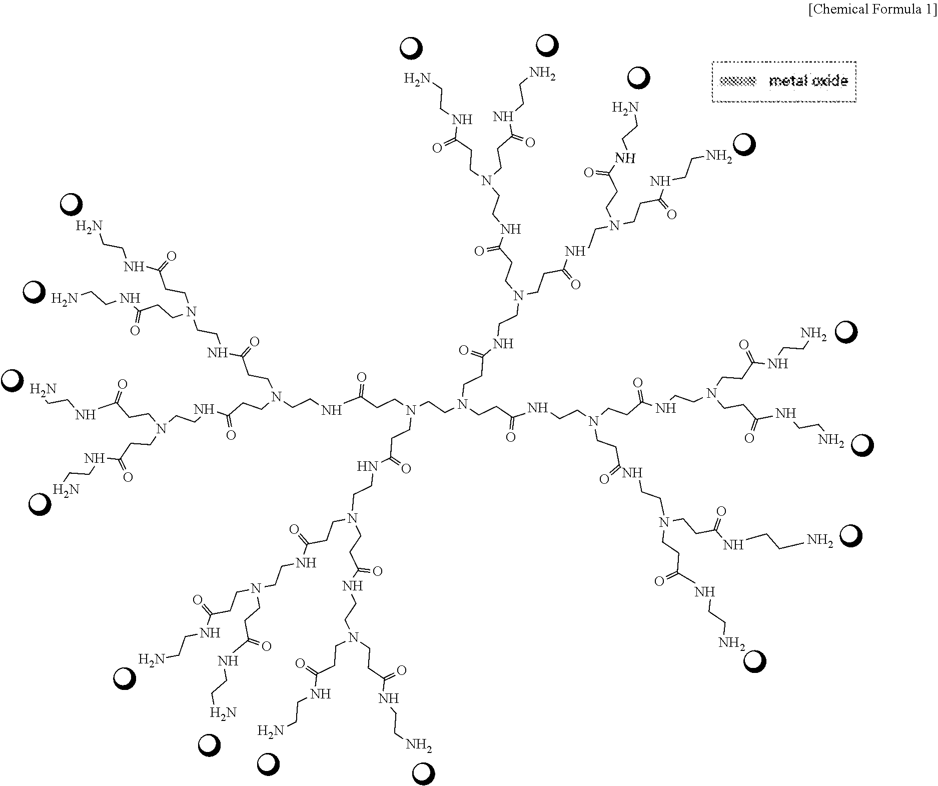 [SMILES: NCCNC(=O)CCN(CCNC(=O)CCN(CCNC(=O)CCN(CCC(=O)NCCN(CCC(=O)NCCN(CCC(=O)NCCN)CCC(=O)NCCN)CCC(=O)NCCN(CCC(=O)NCCN)CCC(=O)NCCN)CCN(CCC(=O)NCCN(CCC(=O)NCCN(CCC(=O)NCCN)CCC(=O)NCCN)CCC(=O)NCCN(CCC(=O)NCCN)CCC(=O)NCCN)CCC(=O)NCCN(CCC(=O)NCCN(CCC(=O)NCCN)CCC(=O)NCCN)CCC(=O)NCCN(CCC(=O)NCCN)CCC(=O)NCCN)CCC(=O)NCCN(CCC(=O)NCCN)CCC(=O)NCCN)CCC(=O)NCCN]

In addition, when the dendrimer particles 20 are polypropyleneimine (PPI), the abrasive, that is the dendrimer particles (surface-treated with metal oxide) 10, may be represented by Chemical Formula 2.

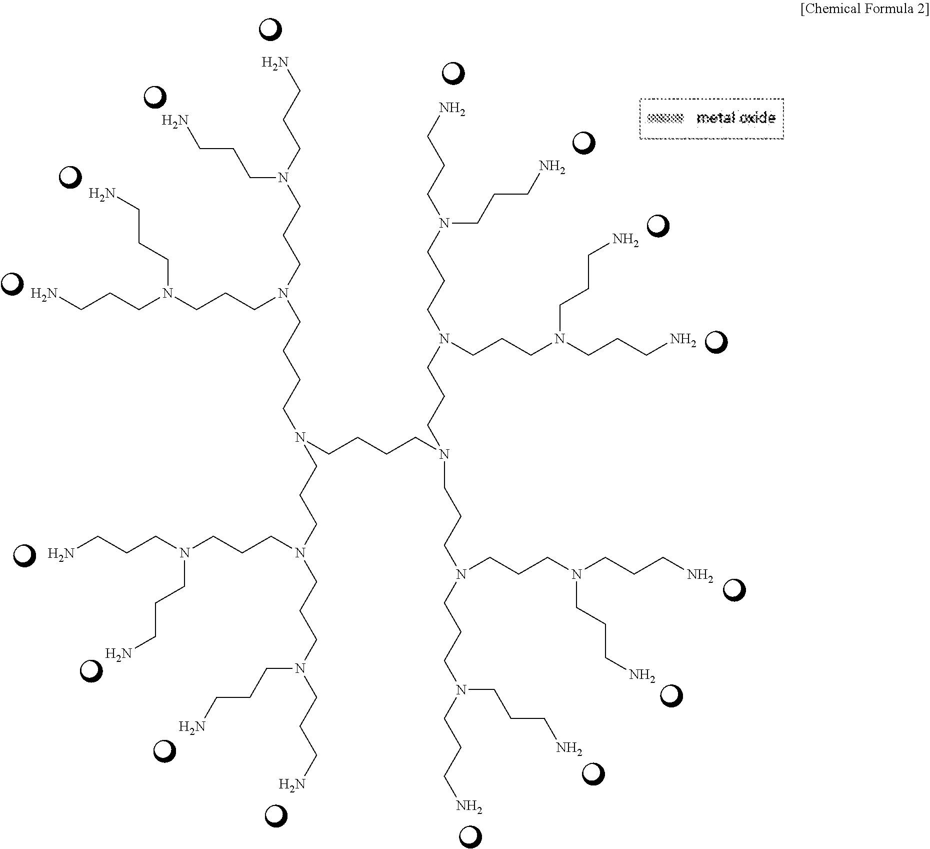 [SMILES: NCCCN(CCCN)CCCN(CCCCN(CCCCN(CCCN(CCCN(CCCN)CCCN)CCCN(CCCN)CCCN)CCCN(CCCN(CCCN)CCCN)CCCN(CCCN)CCCN)CCCN(CCCN(CCCN)CCCN)CCCN(CCCN)CCCN)CCCN(CCCN)CCCN]

The dendrimer particles 20 may be nanoparticles. For example, the dendrimer particle 20 may have a size of about 1 nm (nanometer) to about 1 μm (micrometer), for example, about 1 nm to about 100 nm. The size of the dendrimer particle 20 refers to an average diameter of the particle. If the dendrimer particle 20 has a size within the ranges, an abrasive with an appropriate size may suppress scratches and defects as well as exhibit excellent polishing performance.

The metal oxide 30 on the surface of the dendrimer particles 20, specifically surrounding at least a portion of the surface of the dendrimer particles 20, may include silica (SiO₂), alumina (Al₂O₃), ceria (CeO₂), zirconia (ZrO₂), titania (TiO₂), a combination thereof, and/or the like.

The metal oxide 30 may react with a reactive group at the terminal end of the dendrimer particle 20 and thus surround the surface of the dendrimer particle 20.

The metal oxide 30 may be spherical shaped or non-spherical shaped particles. If the metal oxide 30 is composed of particles, the particles may have an average size of about 10 nm to about 300 nm, for example, about 20 nm to about 280 nm. Herein, the particle size means a diameter based on a long-axis (e.g., the major axis). If the metal oxide 30 has a particle size within the ranges, polishing performance may be improved.

Additionally, the metal oxide 30 may have a structure of nano wrinkles, nano spikes, or a combination thereof. If the metal oxide has these structures, a higher polishing rate and stability may be achieved. Specifically, if the metal oxide 30 has a nano-wrinkle structure, as its aqueous solution may be easily diffused, and the surface of the metal oxide 30 is creased, the metal oxide 30 may have a larger area available for a reaction. In addition, if the metal oxide 30 has a nanospike structure, charge density increases toward the end of the surface protrusions, increasing reactivity.

A method of preparing the dendrimer particles (surface-treated with metal oxide) 10 will be described later.

The abrasive, that is dendrimer particles (surface-treated with metal oxide) 10 may be included in an amount of about 0.001 wt % to about 20 wt %, for example about 0.01 wt % to about 15 wt % based on a total amount of the slurry composition for chemical mechanical polishing. When the abrasive is included within the content ranges, excellent polishing performance may not only be achieved, but also scratch and defect generation may be minimized.

In addition to the abrasive, the slurry composition for chemical mechanical polishing according to at least one embodiment may further include a carrier and/or additives such as an oxidant, a catalyst, an organic acid, a surfactant, a polishing accelerator, a pH control agent, a dispersion stabilizer, a polishing inhibitor, a leveling agent, a corrosion inhibitor, an amine compound, or a combination thereof.

### Oxidant

The oxidant can oxidize the wafer, specifically the wafer with an oxide film, to facilitate polishing.

Examples of the oxidant may include an inorganic percompound, an organic percompound, bromic acid or a salt thereof, nitric acid or a salt thereof, chloric acid or a salt thereof, chromic acid or a salt thereof, iodic acid or a salt thereof, iron or a salt thereof, copper or a salt thereof, a rare earth metal oxide, a transition metal oxide, potassium dichromate, and/or the like, and these may be used alone or in a mixture of two or more. Here, “percompound” may mean a compound including one or more peroxide groups (—O—O—) or including an element in the highest oxidation state. For example, the oxidant may include a peroxide (e.g., hydrogen peroxide, potassium periodide, calcium persulfate, potassium ferricyanide, etc.).

The oxidant may be included in an amount of about 0.01 wt % to about 20 wt %, for example about 0.05 wt % to about 15 wt %, about 0.1 wt % to about 10 wt %, based on a total amount of the slurry composition for chemical mechanical polishing. If the oxidant is included in the above content range, the polishing rate of the wafer can be improved.

### Catalyst

The catalyst can improve the polishing rate of wafers, particularly wafers of oxide films.

Examples of the catalyst may include an iron ion compound, an iron ion complex, and/or a hydrate thereof.

The iron ion compound may include, for example, a compound including iron trivalent cations. The compound including the iron trivalent cation is not particularly limited as long as it is a compound in which the iron trivalent cation exists as a free cation in an aqueous solution, and examples thereof may include iron chloride (FeCl₃), iron nitrate (Fe(NO₃)₃), iron sulfate (Fe₂(SO₄)₃), etc., but are not limited thereto.

The complex compound of the iron ion may include, for example, a complex including an iron trivalent cation. The complex compound including the iron trivalent cation may include a compound formed by reacting iron trivalent cations with an organic or inorganic compound including at least one functional group from, for example, carboxylic acids, phosphoric acids, sulfuric acids, amino acids, and amines in an aqueous solution.

Examples of the organic or inorganic compound may include citrate, ammonium citrate, paratoluenesulfonic acid (pTSA), 1,3-propylenediaminetetraacetic acid (PDTA), ethylenediaminetetraacetic acid (EDTA), diethylenetriaminepentaacetic acid (DTPA), nitrilotriacetic acid (NTA), EDDS (ethylenediamine-N,N′-disuccinic acid), and/or the like. The complex compound including the iron trivalent cation may include, for example, ferric citrate, ferric ammonium citrate, Fe(III)-pTSA, Fe(III)-PDTA, and Fe(III)-EDTA, but is not limited thereto.

The catalyst may be included in an amount of about 0.001 wt % to about 10 wt %, for example about 0.001 wt % to about 5 wt %, about 0.001 wt % to about 1 wt %, based on a total amount of the slurry composition for chemical mechanical polishing. If the catalyst is included in the above content range, the polishing rate of the wafer can be improved.

### Organic Acid

The organic acid can maintain the pH of the slurry composition for chemical mechanical polishing stable.

Examples of the organic acid may include carboxylic acids such as malonic acid, maleic acid, and malic acid, and amino acids such as glycine, isoleucine, leucine, phenylalanine, methionine, threonine, tryptophan, valine, alanine, arginine, cysteine, glutamine, histidine, proline, serine, tyrosine, and lysine.

The organic acid may be included in an amount of about 0.001 wt % to about 10 wt %, for example about 0.002 wt % to about 5 wt %, about 0.005 wt % to about 1 wt %, based on the total amount of the slurry composition for chemical mechanical polishing. If the organic acid is included in the above content range, the pH can be maintained more stably.

In addition to the aforementioned components, the additive may further include a pH control agent, a polishing accelerator, a surfactant, a polishing inhibitor, a leveling agent, a corrosion inhibitor, an amine compound, a chelator, a carrier, or a combination thereof.

### pH Control Agent

The slurry composition for chemical mechanical polishing may further include a pH control agent for regulating pH of the composition. The slurry composition for chemical mechanical polishing may have a pH of 1 to 9, for example, 2 to 7.

The pH control agent may include an acid solution such as sulfuric acid, phosphoric acid, hydrochloric acid, nitric acid, carboxylic acid, maleic acid, malonic acid, citric acid, oxalic acid, and tartaric acid; an alkaline solution such as calcium hydroxide, potassium hydroxide, ammonium hydroxide, sodium hydroxide, magnesium hydroxide, triethylamine, tetramethylammonium hydroxide, or ammonia; or a combination thereof, but is not limited thereto.

The pH control agent may be included in the slurry composition for chemical mechanical polishing in an amount that allows the slurry composition to have and maintain a desired pH.

### Polishing Accelerator

The polishing accelerator widely used in chemical mechanical polishing may include an anionic-based low-molecular weight material, an anionic-based high-molecular weight material, a hydroxyl acid, or an amino acid.

The anionic-based low-molecular weight material may include, for example, at least one of citric acid, polyacrylic acid, polymethacrylic acid, and/or a copolymer acid or salt thereof. The hydroxyl acid may include, for example, at least one of hydroxylbenzoic acid, ascorbic acid, or a salt thereof. The amino acid may include, for example, picolinic acid, serine, proline, arginine, asparagine, aspartic acid, cysteine, glutamine, glutamic acid, glycine, histidine, lysine, phenylalanine, tyrosine, valine, tryptophan, betaine, pyroglutamic acid, amino butyric acid, pyridine carboxylic acid, polyethylene glycol amino ether acetatic acid, and isoleucine.

Additional examples of the polishing accelerator may include a quinone compound such as 3-hydroxy-4-methyl-phenol anion or 3-hydroxy-4-hydroxymethyl-phenol anion, 4-methyl-benzene-1,3-diol, kojic acid, maltol propionate, maltol isobutyrate, and/or the like.

Specific examples of the quinone compound may include 4-alkyl-benzene-1,3-diol, 3-hydroxy-4-alkyl-cyclohexa-2,5-dienone, 6-alkyl-3-oxo-cyclohexa-1,4-dienol anion, 3-hydroxy-6-alkyl-cyclohexa-2,4-dienone, 4-alkyl-3-oxo-cyclohexa-1,5-dienol anion, 3-hydroxy-4-alkyl-phenol anion, 5-hydroxy-2-alkyl-phenol anion, 3-hydroxy-4-alkyl-phenol anion, 5-hydroxy-2-hydroxyalkyl-phenol anion, 3-hydroxy-4-hydroxyalkyl-phenol anion, 3-hydroxy-4-hydroxyalkyl-cyclohexa-2,5-dienone, 6-hydroxyalkyl-3-oxo-cyclohexa-1,4-dienol anion, 3-hydroxy-6-hydroxyalkyl-cyclohexa-2,4-dienone, 4-hydroxyalkyl-3-oxo-cyclohexa-1,5-dienol anion, 4-hydroxyalkyl-benzene-1,3-diol, and/or the like.

Other additional examples of the polishing accelerator may include ammonium hydrogen phosphate, ammonium dihydrogen phosphate, bis(2-ethylhexyl)phosphate, 2-aminoethyl dihydrogen phosphate, 4-chlorobenzenediazonium hexafluorophosphate, nitrobenzenediazonium hexafluorophosphate, ammonium hexafluorophosphate, bis(2,4-dichlorophenyl) chlorophosphate, bis(2-ethylhexyl) hydrogenphosphate, bis(2-ethylhexyl)phosphite, calcium fluorophosphate, diethyl chlorophosphate, diethyl chlorothiophosphate, potassium hexafluorophosphate, pyrophosphoric acid, tetrabutylammonium hexafluorophosphate, tetraethylammonium hexafluorophosphate, and/or the like.

### Dispersion Stabilizer

The slurry composition for chemical mechanical polishing may further include a dispersion stabilizer to ensure dispersion stability of the polishing particles.

The dispersion stabilizer may include a non-ionic polymer and/or a cationic organic compound. The dispersion stabilizer may include, for example, at least one selected from the group consisting of ethylene oxide, ethylene glycol, glycol distearate, glycol monostearate, glycol polymerate, glycol ethers, alcohols including alkylamines, a compound including polymerate ether, vinyl pyrrolidone, cellulose, ethoxylate compounds, and/or the like. Specifically, the dispersion stabilizer may include at least one selected from the group consisting of diethylene glycol hexadecyl ether, decaethylene glycol hexadecyl ether, diethylene glycol octadecyl ether, eicosaethylene glycol octadecyl ether, diethylene glycol oleyl ether, decaethylene glycol oleyl ether, decaethylene glycol octadecyl ether, nonylphenol polyethylene glycol ether, ethylenediamine tetrakis(ethoxylate-block-propoxylate) tetrol, ethylenediamine tetrakis(propoxylate-block-ethoxylate) tetrol, polyethylene-blockpoly(ethylene glycol, polyoxyethylene isooctylphenyl ether, polyoxyethylene octylphenyl ether, polyoxyethylene tridecyl ether, polyoxyethylene sorbitan tetraoleate, polyoxyethylene sorbitol hexaoleate, polyethylene glycol sorbitan monolaurate, polyoxyethylene sorbitan monolaurate, sorbitan monopalmitate, FS-300 nonionic fluorosurfactant, FSN nonionic fluorosurfactant, FSO nonionic ethoxylated fluorosurfactant, vinyl pyrrolidone, 2,4,7,9-tetramethyl-5-decyne-4,7-diol ethoxylate, 8-methyl-1-nonanol propoxylate-block-ethoxylate, allyl alcohol 1,2-butoxylate-block-ethoxylate, polyoxyethylene branched nonylcyclohexyl ether, polyoxyethylene isooctylcyclohexyl ether, and/or a combination thereof.

The dispersion stabilizer may be included in an amount of about 0.1 wt % to about 1 wt % based on a total amount of the slurry composition for chemical mechanical polishing.

### Surfactant

The surfactant may be appropriately selected and used from a nonionic-based surfactant, a cationic-based surfactant, an anionic-based surfactant, and an amphoteric surfactant.

The nonionic-based surfactant may include polyoxyethylene alkyl ethers such as polyoxyethylene lauryl ether and polyoxyethylene stearyl ether; polyoxyethylene alkyl phenyl ethers such as polyoxyethylene octyl phenyl ether and polyoxyethylene nonierphenyl ether; sorbitan higher fatty acid esters such as sorbitan monolaurate, sorbitan monostearate, and sorbitan trioleate; polyoxyethylene sorbitan higher fatty acid esters such as polyoxyethylene sorbitan monolaurate; polyoxyethylene higher fatty acid esters such as polyoxyethylene monolaurate and polyoxyethylene monostearate; glycerin higher fatty acid esters such as oleic acid monoglyceride and stearic acid monoglyceride; polyoxyalkylenes such as polyoxyethylene, polyoxypropylene, and polyoxybutylene, and a block copolymer thereof.

The cationic-based surfactant may include alkyl trimethyl ammonium chloride, dialkyl dimethyl ammonium chloride, a benzalkonium chloride salt, alkyl dimethyl ammonium ethosulfate, and the like.

The anionic-based surfactant may include carboxylic acid salts such as lauric acid sodium, oleic acid sodium, N-acyl-N-methylglycine sodium salts, and polyoxyethylene laurylether carboxylic acid sodium; sulfonates such as dodecylbenzene sulfonic acid sodium, dialkyl sulfosuccinate ester salts, and dimethyl-5-sulfoisophthalate sodium; ester sulfates such as sodium lauryl sulphate, sodium polyoxyethylene lauryl ether sulphate, and polyoxyethylene nonylphenyl ether sodium sulfate; ester phosphates such as polyoxyethylene lauryl sodium phosphate and polyoxyethylene nonylphenyl ether sodium phosphate, and the like.

The amphoteric surfactant may include a carboxybetaine surfactant, an aminocarboxylic acid salt, imedazolinium betaine, lecithin, alkylamineoxide, and the like.

The surfactant may be included in an amount of about 0.001 wt % to about 1.0 wt %, for example about 0.01 wt % to about 0.5 wt % based on a total amount of the slurry composition for chemical mechanical polishing.

### Polishing Inhibitor

The polishing inhibitor may include a nitrogen-containing compound such as amines and low-molecular weight nitrogen-containing heterocyclic compounds. The polishing inhibitor may be selected to inhibit over-polishing, such that the removal of some of the elements (e.g., the SiN of FIG. 2) is inhibited. Specific examples may include benzotriazole, 1,2,3-triazole, 1,2,4-triazole, and the like.

The polishing inhibitor may be included in an amount of about 0.1 wt % to about 1 wt % based on a total amount of slurry composition for chemical mechanical polishing.

### Leveling Agent

The leveling agent can reduce irregularities of a surface to be polished, and may include, for example, ammonium chloride, ammonium lauryl sulfate, polyethylene glycol, triethanolamine polyoxyethylene alkyl ether sulfate, polyvinylpyrrolidone, polyacrolein, and the like.

The leveling agent may be included in an amount of about 0.01 wt % to about 1.0 wt %, for example about 0.1 wt % to about 1.0 wt % based on a total amount of the slurry composition for chemical mechanical polishing.

### Corrosion Inhibitor

The corrosion inhibitor can protect a surface to be polished from corrosion, and can improve recess, erosion, roughness, and the like.

The corrosion inhibitor may include triazole and a derivative thereof, benzene triazole and a derivative thereof, a combination thereof, and/or the like. The triazole derivatives may include, for example, an amino-substituted triazole compound, a bi-amino-substituted triazole compound, and/or the like, but is not limited thereto.

The corrosion inhibitor may be included in an amount of about 0.001 wt % to about 1.0 wt %, for example about 0.01 wt % to about 0.5 wt % based on a total amount of the slurry composition for chemical mechanical polishing.

### Amine Compound

The amine compound may be a compound having 1 to 20 carbon atoms and having two or more amine groups in one molecule. The amine compound may include, for example, diamines, triamines, tetramines, pentamines, hexamines, heptamines, and the like. Specific examples of the amine compound may be one or more of spermine, methane diamine, ethane-1,2-diamine, propane-1,3-diamine, butane-1,4-diamine, pentane-1,5-diamine, hexane-1,6-diamine, heptane-1,7-diamine, octane-1,8-diamine, diethylene triamine, dipropylene triamine, triethylenetetramine (TETA), tripropylene tetramine, tetraethylene pentamine (TEPA), pentaethylenehexamine (PEHA), hexaethylene heptamine, bis(hexamethylene)triamine, N-(3-aminopropyl)ethylenediamine, N,N′-bis(3-aminopropyl)ethylenediamine, N,N′-bis(2-aminoethyl)-1,3-propanediamine, N,N,N′-tris(3-aminopropyl)ethylenediamine, N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, N,N,N′N′-tetrakis(2-hydroxylpropyl)ethylenediamine, N,N,N′,N′-tetramethyl propanediamine, di-t-butylethylenediamine, 3,3′-iminobis(propylamine), N-methyl-3,3′-iminobis(propylamine), N,N′-bis(3-aminopropyl)-1,3-propylenediamine, N,N′-bis(3-aminopropyl)-1,4-butylenediamine, N,N′-bis(4-aminobutyl)-1,4-butanediamine, N,N′-bis(2-aminoethyl)-1,4-butanediamine, N,N′-bis(2-aminoethyl)ethylenediamine, bis(3-aminopropyl)amine, bis(4-aminobutyl)amine, bis(5-aminopentyl)amine, N-(6-aminohexyl)-1,6-hexanediamine, hexahydro-1,3,5-triazine, N-methylethylenediamine, N-ethylethylenediamine, N-propylethylenediamine, N-butylethylenediamine, N-methyl-1,3-diaminopropane, N-methyl-1,4-diaminobutane, N-methyl-1,5-diaminopentane, N-methyl-1,6-diaminohexane, N-methyl-1,7-diaminoheptane, N-methyl-1,8-diaminoctane, N-methyl-1,9-diaminononane, N-methyl-1,10-diaminodecane, N-methyl-1,11-diaminoundecane, N-methyl-1,12-diaminododecane, 1,3-bis(aminomethyl)cyclohexane, 1,4-bis(aminomethyl)cyclohexane, piperazine, a derivative thereof, but are not limited thereto.

The amine compound may be included in an amount of about 0.001 wt % to about 1 wt %, for example about 0.005 wt % to about 0.5 wt % based on a total amount of the slurry composition for chemical mechanical polishing.

### Carrier

The carrier may be a liquid in which the abrasive and/or additives are substantially uniformly dispersed, and may be for example, may be an aqueous solvent or an organic solvent.

The carrier may include, for example, water, deionized water, ultrapure water, alcohol (e.g., propenyl alcohol, isopropyl alcohol, ethanol, 1-propanol, methanol, 1-hexanol, and the like), aldehyde (e.g., formaldehyde, acetaldehyde, and the like), ester (e.g., ethyl formate, propyl formate, ethyl acetate, methyl acetate, methyl lactate, butyl lactate, ethyl lactate, and the like), ketone (e.g., acetone, diacetone alcohol, methyl ethyl ketone, and the like), dimethyl sulfoxide, tetrahydrofuran, dioxane, diglyme, amide (e.g., N,N-dimethyl formamide, dimethyl imidazolidinone, N-methyl pyrrolidone, and the like), polyhydric alcohol and a derivative thereof (e.g., ethylene glycol, glycerol, diethylene glycol, diethylene glycol monomethyl ether, and the like), a nitrogen-containing organic compound (e.g., acetonitrile, amylamine, isopropylamine, imidazole, dimethyl amine, and the like), and/or a mixture thereof.

The carrier may be included as a balance amount based on a total amount of the slurry composition for chemical mechanical polishing.

The components of the aforementioned dendrimer particles (surface-treated with metal oxide) 10 may be analyzed by Raman analysis, Fourier transform infrared spectroscopy (FTIR), X-ray photoelectron spectroscopy (XPS), scanning electron microscopy (SEM), and transmission electron microscopy (TEM).

Hereinafter, a method for preparing a slurry composition for chemical mechanical polishing according to at least one embodiment will be described.

The slurry composition for chemical mechanical polishing according to at least one embodiment may be prepared by preparing the aforementioned abrasive, that is, the dendrimer particles (surface-treated with metal oxide) 10, and then mixing the abrasive and optionally the carrier and/or one or more of the above additives.

The dendrimer particles (surface-treated with metal oxide) 10 include may be obtained by obtaining dendrimers from reactants through a Michael addition reaction; and mixing the dendrimer with a metal oxide precursor to obtain a mixture.

The Michael addition reaction is a nucleophilic addition reaction with a compound having an electron-withdrawing double bond, such as an α,β-unsaturated ketone, and a compound with a highly active methylene group.

The reactant may include ammonia, an amine compound, or a combination thereof, where the amine compound may include ethylenediamine, 1,4-diaminobutane, or a combination thereof.

As an example, a dendrimer of poly(amidoamine) (PAMAM) can be synthesized from ammonia or ethylenediamine by repeating a Michael addition reaction and an amidation reaction. As another example, dendrimer of polypropyleneimine (PPI) can be synthesized from 1,4-diaminobutane by Michael addition reaction.

The metal oxide precursor may include a silica (SiO₂) precursor, an alumina (Al₂O₃) precursor, a ceria (CeO₂) precursor, a zirconia (ZrO₂) precursor, a titania (TiO₂) precursor, and/or a combination thereof.

The silica (SiO₂) precursors may include, for example, tetraethylorthosilicate (TEOS), tetramethylorthosilicate (TMOS), and the like. The alumina (Al₂O₃) precursor may include, for example, aluminum nitrate (Al(NO₃)₃·9H₂O), aluminum isopropoxide (Al[OCH(CH₃)₂]₃), aluminum chloride (AlCl₃·6H₂O), aluminum acetate (C2H₅AlO₄), and the like. The ceria (CeO₂) precursor may include, for example, cerium nitrate (Ce(NO₃)₃·6H₂O), cerium chloride, cerium acetate, and the like. The zirconia (ZrO₂) precursor may include, for example, zirconium nitrate (Zr(NO₃)₂·2H₂O), zirconium chlorooxide (ZrCl₂O·8H₂O), and/or the like. The titania (TiO₂) precursor may include, for example, titanium isopropoxide.

As an example, dendrimer particles of poly(amidoamine) (PAMAM) surface-treated with silica can be sequentially prepared according to Reaction Scheme 1 and Reaction Scheme 2.

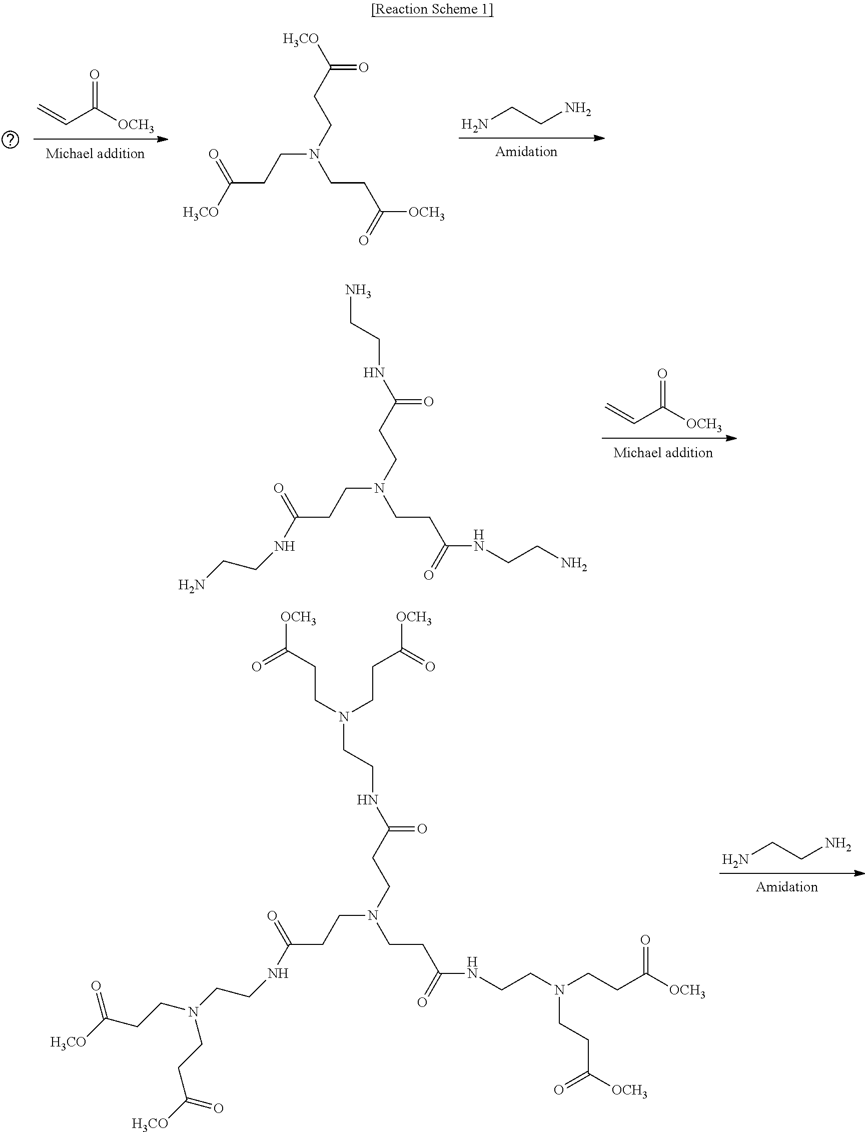

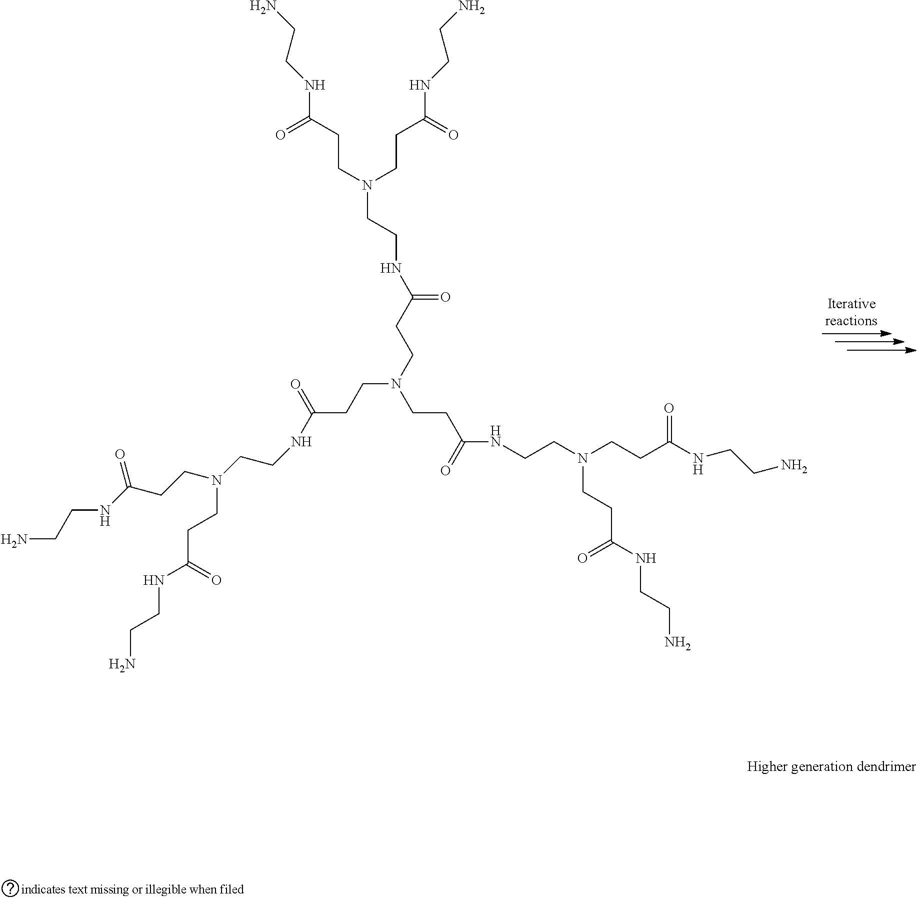 [SMILES: NCCNC(=O)CCN(CCNC(=O)CCN(CCC(=O)NCCN(CCC(=O)NCCN)CCC(=O)NCCN)CCC(=O)NCCN(CCC(=O)NCCN)CCC(=O)NCCN)CCC(=O)NCCN]

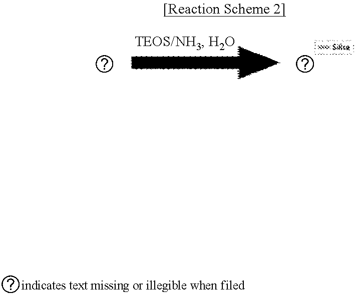

After obtaining the mixture, a further step of centrifugation and redispersion in alcohol may be performed.

The centrifugation may be performed at a speed of about 5000 rotations per minute (rpm) to about 15000 rpm, for example about 7000 rpm to about 13000 rpm, for about 5 minutes to about 30 minutes, for example about 10 minutes to about 20 minutes. When centrifugation is performed under conditions within the above range, dendrimer particles surface-treated with metal oxide of an appropriate size can be obtained. Accordingly, polishing performance is improved and scratches during polishing can be reduced.

The alcohol may be, for example, C1 to C4 alcohol.

The aforementioned abrasive, that is, the dendrimer particles (surface-treated with metal oxide) 10, may be mixed in an amount of about 0.001 wt % to about 20 wt %, for example about 0.01 wt % to about 15 wt %, based on a total amount of the slurry composition for chemical mechanical polishing. If the abrasive is mixed within the above content range, a slurry composition for chemical mechanical polishing that has excellent polishing performance and reduces the occurrence of scratches and defects can be obtained.

According to at least one embodiment, a wafer, specifically a wafer including an oxide film, can be polished at a high polishing rate while suppressing the occurrence of scratches or defects on the surface using the slurry composition for chemical mechanical polishing.

Hereinafter, the embodiments are illustrated in more detail with reference to examples. However, the following examples are for illustrative purposes only and do not limit the scope of rights.

### Example 1

100 ml of an aqueous solution of the 2-generation poly(amidoamine) (PAMAM) synthesized according to Reaction Scheme 1 was repeatedly mixed and stirred with 50 ml of tetraethylorthosilicate (TEOS) and 50 ml of a dimethylamine aqueous solution (20 wt %) and then, maintained for 10 hours.

Subsequently, the resulting mixture was centrifuged at 8500 rpm for 15 minutes and then redispersed in ethanol and washed to prepare dendrimer particles surface-treated with silica.

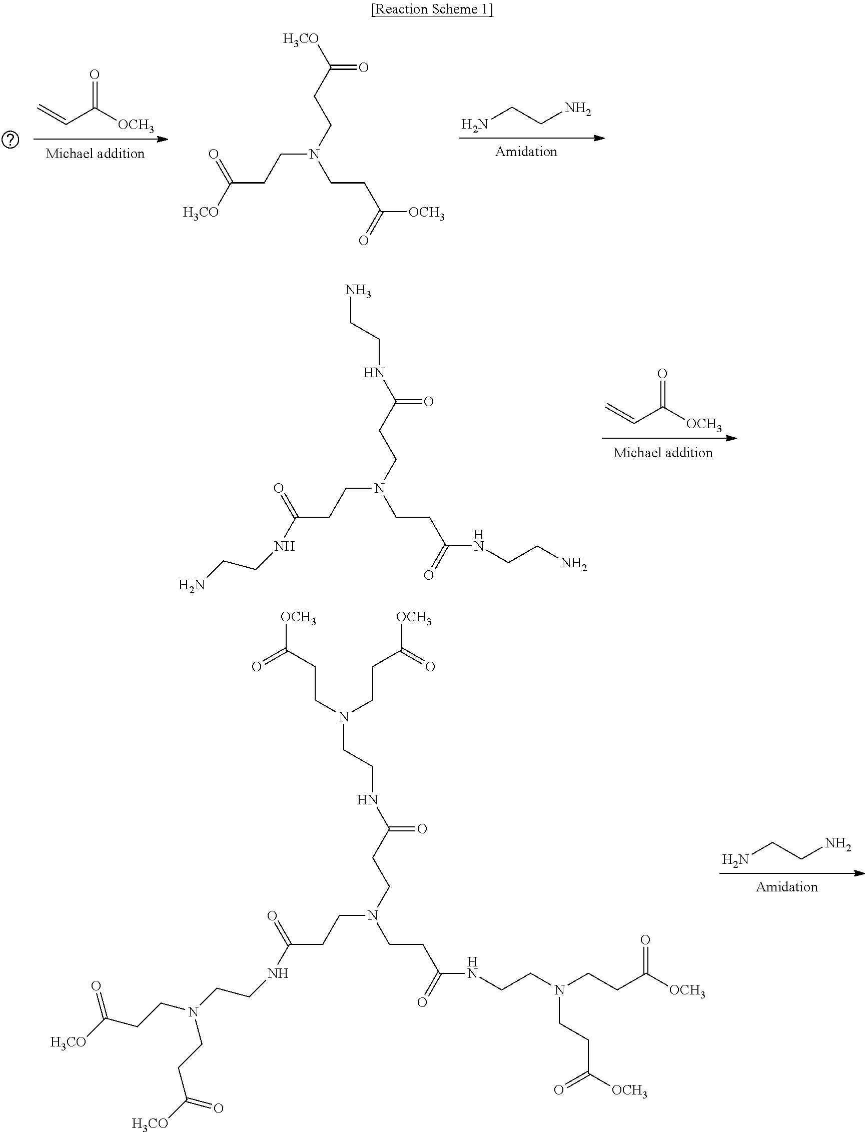

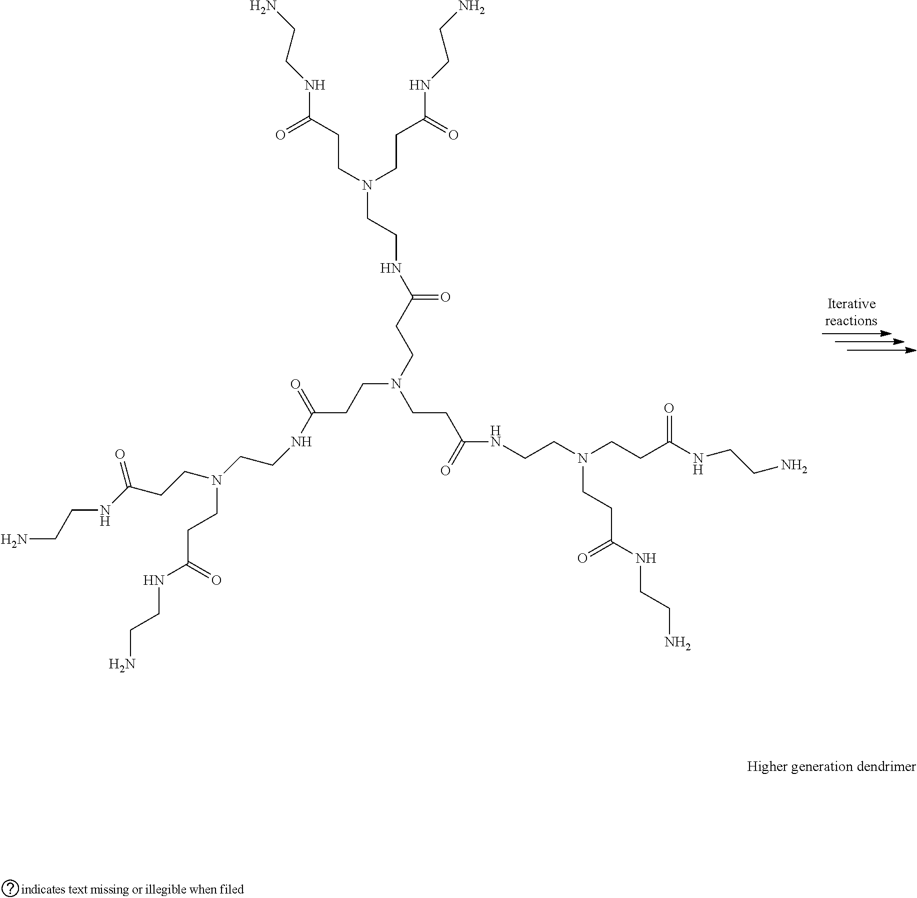 [SMILES: NCCNC(=O)CCN(CCNC(=O)CCN(CCC(=O)NCCN(CCC(=O)NCCN)CCC(=O)NCCN)CCC(=O)NCCN(CCC(=O)NCCN)CCC(=O)NCCN)CCC(=O)NCCN]

Subsequently, 1 wt % of the dendrimer particles surface-treated with metal oxide as an abrasive was mixed with 0.03 wt % of iron nitrate 9 hydrate as a catalyst, 0.04 wt % of malonic acid as organic acid, 0.04 wt % of glycine, 0.05 wt % of hydrogen peroxide as an oxidant, and a balance amount of deionized water as a solvent to prepare a slurry composition.

### Example 2

A slurry composition was prepared in the same manner as in Example 1 except that a 3-generation poly(amidoamine) (PAMAM) aqueous solution was used instead of the 2-generation poly(amidoamine) (PAMAM) aqueous solution.

### Example 3

A slurry composition was prepared in the same manner as in Example 1 except that a 4-generation poly(amidoamine) (PAMAM) aqueous solution was used instead of the 2-generation poly(amidoamine) (PAMAM) aqueous solution.

### Example 4

A slurry composition was prepared in the same manner as in Example 1 except that aluminum isopropoxide (Al[OCH(CH₃)₂]₃) was used instead of TEOS and the dimethylamine aqueous solution.

### Example 5

A slurry composition was prepared in the same manner as in Example 1 except that zirconium nitrate (Zr(NO₃)₂·2H₂O) was used instead of TEOS and the dimethylamine aqueous solution.

### Comparative Example 1

A slurry composition was prepared by mixing 1 wt % of silica (PL-1 with a primary particle diameter of 15 nm, FUSO Chemical Co., Ltd.), 0.03 wt % of iron nitrate 9 hydrate, 0.04 wt % of malonic acid, 0.04 wt % of glycine, 0.05 wt % of hydrogen peroxide, and a balance amount of deionized water.

### Comparative Example 2

A slurry composition was prepared by mixing 0.5 wt % of silica (PL-1 with a primary particle diameter of 15 nm, FUSO Chemical Co., Ltd.), 0.5 wt % of poly(amidoamine) (PAMAM) synthesized according to Reaction Scheme 1, 0.03 wt % of iron nitrate 9 hydrate, 0.04 wt % of malonic acid, 0.04 wt % of glycine, 0.05 wt % of hydrogen peroxide, and a balance amount of deionized water.

### Evaluation 1: Polishing Performance

Each of the slurry compositions according to Examples 1 to 5 and Comparative Examples 1 and 2 was used to polish an oxide film wafer and then check a polishing rate. The polishing rate was measured under the following conditions, and the results are shown in Table 1.

A Uniplar 231 (Doosan Mechatec Co., Ltd.) polisher was used with a polishing pad H800 (Fujibo Ehime Co., Ltd.) at polishing platen speed of 24 rpm, a polishing pressure of 3 psi, and a flow rate of 200 cc/min.

In Table 1, the polishing rate was obtained by measuring a film thickness change before and after the polishing.

TABLE 1

| | Polishing rate (Å/min) |
|---|---|
| Example 1 | 750 |
| Example 2 | 743 |
| Example 3 | 738 |
| Example 4 | 735 |
| Example 5 | 730 |
| Comparative Example 1 | 700 |
| Comparative Example 2 | 480 |

Referring to Table 1, Examples 1 to 5, in which the dendrimer particles surface-treated with metal oxide were used as an abrasive, exhibited excellent polishing performance, compared with Comparative Example 1, in which silica was used as an abrasive, and Comparative Example 2, in which the silica and the dendrimer particles were used.

### Evaluation 2: Defect Evaluation

Each of the slurry compositions of Examples 1 to 5 and Comparative Examples 1 and 2 was used to polish an oxide film wafer and then, check defects, and the results are shown in Table 2.

The number of defects of the oxide film after the polishing was counted by using AIT-XP of KLA Tencor.

TABLE 2

| | Number of defects |
|---|---|
| Example 1 | 24 |
| Example 2 | 27 |
| Example 3 | 30 |
| Example 4 | 35 |
| Example 5 | 36 |
| Comparative Example 1 | 510 |
| Comparative Example 2 | 250 |

Referring to Table 2, Examples 1 to 5, in which the dendrimer particles surface-treated with metal oxide were used as an abrasive, were significantly suppressed from generating the defects on the oxide film surface, compared with Comparative Example 1, in which silica was used as an abrasive, and Comparative Example 2, in which the silica and the dendrimer particles were mixed.

Although some embodiments of the present disclosure have been described in detail, the scope of the present disclosure is not limited thereto, and various modifications and improvements made by one skilled in the art by using the basic concept of the present disclosure defined in the following claims also fall within in the scope of the present disclosure.

What is claimed is:

1. A slurry composition for chemical mechanical polishing, comprising:
an abrasive including dendrimer particles surface-treated with metal oxide, wherein the dendrimer particles surface-treated with metal oxide comprises dendrimer particles, and
a metal oxide surrounding at least a portion of an outer surface of the dendrimer particles.

2. The slurry composition for chemical mechanical polishing of claim 1, wherein
the dendrimer particles are composed of a dendritic polymer, and
a generation number of the dendritic polymer is an integer within a range of 1 to 10.

3. The slurry composition for chemical mechanical polishing of claim 1, wherein each of the dendrimer particles comprises an amino group, a hydroxy group, a carboxyl group, an acetyl group, a mannose group, a galactose group, or a combination thereof at a terminal end of the dendrimer particles.

4. The slurry composition for chemical mechanical polishing of claim 1, wherein the dendrimer particles comprise poly(amidoamine) (PAMAM), polypropyleneimine (PPI), or a combination thereof.

5. The slurry composition for chemical mechanical polishing of claim 1, wherein the dendrimer particles are nanoparticles having an average size within a range of 1 nm to 1 μm.

6. The slurry composition for chemical mechanical polishing of claim 1, wherein the metal oxide comprises silica (SiO₂), alumina (Al₂O₃), ceria (CeO₂), zirconia (ZrO₂), titania (TiO₂), or a combination thereof.

7. The slurry composition for chemical mechanical polishing of claim 1, wherein a structure of the metal oxide includes nano wrinkles, nano spikes, or a combination thereof.

8. The slurry composition for chemical mechanical polishing of claim 1,
wherein the metal oxide is particles having an average size within a range of 10 nm to 300 nm.

9. The slurry composition for chemical mechanical polishing of claim 1, wherein the abrasive is included in an amount within a range of 0.001 wt % to 20 wt % based on a total amount of the slurry composition.

10. The slurry composition for chemical mechanical polishing of claim 1 further comprising:
an oxidant, a catalyst, an organic acid, or a combination thereof.

11. A method of preparing a slurry composition for chemical mechanical polishing, comprising:
preparing an abrasive including dendrimer particles surface-treated with metal oxide, wherein the dendrimer particles surface-treated with metal oxide comprises dendrimer particles, and
a metal oxide surrounding at least a portion of an outer surface of the dendrimer particles.

12. The method of claim 11, wherein the dendrimer particles surface-treated with metal oxide is obtained by:
obtaining dendrimers from reactants through a Michael addition reaction; and
reacting the obtained dendrimer with a metal oxide precursor to obtain the dendrimer particles surface-treated with metal oxide.

13. The method of claim 12, wherein
the reactant comprises at least one of an ammonia, ethylenediamine, 1,4-diaminobutane, or a combination thereof.

14. The method of claim 12, wherein the metal oxide precursor comprises at least one of a silica (SiO₂) precursor, an alumina (Al₂O₃) precursor, a ceria (CeO₂) precursor, a zirconia (ZrO₂) precursor, a titania (TiO₂) precursor, or a combination thereof.

15. The method of claim 12, wherein the reacting the obtained dendrimer with the metal oxide precursor includes centrifuging a mixture including the dendrimer and the metal oxide precursor.

16. The method of claim 15, wherein the centrifugation is performed at a speed within a range of 5000 rpm to 15000 rpm for a period within a range of 5 minutes to 30 minutes.

17. The method of claim 11, for comprising:
mixing the abrasive and an additive,
wherein the additive comprises at least one of an oxidant, a catalyst, an organic acid, or a combination thereof.

18. The method of claim 17, wherein the abrasive is mixed in an amount within a range of 0.001 wt % to 20 wt % based on a total amount of the slurry composition for chemical mechanical polishing.

19. A chemical mechanical polishing method of a wafer, the method comprising:
applying the slurry composition for chemical mechanical polishing of claim 1 to the wafer.

20. The chemical mechanical polishing method of claim 19, wherein
the wafer comprises an oxide film.
